(19) United States
(12) Patent Application Publication
(10) Pub. No.: US 2026/0013259 A1
(43) Pub. Date: Jan. 8, 2026

(54) PHOTODETECTOR DEVICE

(71) Applicant: STMicroelectronics International N.V., Geneva (CH)

(72) Inventors: Loic BAUDOIN, Corenc (FR); Arthur ARNAUD, La Tronche (FR)

(73) Assignee: STMicroelectronics International N.V., Geneva (CH)

(21) Appl. No.: 19/257,917

(22) Filed: Jul. 2, 2025

(30) Foreign Application Priority Data
Jul. 5, 2024 (FR) FR2407369

(51) Int. Cl. H10F 77/14; H10F 30/22; H10F 77/20

(52) U.S. Cl. CPC H10F 77/1433; H10F 30/22; H10F 77/206

(57) ABSTRACT

A photodetector device includes a group of pixels. A common reference electrode is shared between the pixels of the group of pixels. A continuous and common colloidal quantum dot thin film is shared by the pixels, including a photosensitive region capable of photogenerating electric charges. An electrode for collecting photogenerated charges is provided for each pixel. The electrodes collecting the charges are configured to collect electrically positive photogenerated charges.

### PRIORITY CLAIM

This application claims the priority benefit of French Application for Patent No. FR2407369, filed on Jul. 5, 2024, the content of which is hereby incorporated by reference in its entirety to the maximum extent allowable by law.

### TECHNICAL FIELD

Embodiments relate to integrated circuits incorporating photodetector devices and, in particular, to photodetector devices using quantum dot colloidal nanoparticle thin film technology.

### BACKGROUND

FIG. 1A illustrates an example of photodetector pixels using a thin film of colloidal quantum dot CQD nanoparticles. The thin layers or films including colloidal semiconductor (nano-) particles (referred to in the art as colloidal quantum dot (CQD) and indicating a zero dimension quantum confinement) make it possible to have a photoelectric effect that is significant and exacerbated with the wavelength corresponding to the excitonic peak characteristic of quantum confinement. These quantum dot films may be integrated into conventional microelectronic manufacturing methods in order to obtain photodiodes.

Conventionally, the photodiode (n-CQD, p-CQD) produced in a colloidal quantum dot CQD thin film is polarized (or biased) between two electrodes E1, E2, at potentials for modulating the outer quantum efficiency of the photoelectric generation, particularly between an “on” state where the quantum efficiency is positive and constant, and an “off” state where the quantum efficiency is substantially zero (See FIG. 2).

The photogenerated charges, that is to say the electric charges generated by photoelectric effect, are collected by the electrodes E1, E2, via layers for transferring respective charges ETL, HTL.

One of the electrodes E1 is referred to as the “collection” electrode, typically provided to collect negative charges (electrons), with which is associated an electron transfer layer ETL located between the electrode E1 and the colloidal quantum dot CQD thin film (n-CQD).

The other electrode E2 is referred to as the “reference” electrode, typically provided to collect positive charges (holes) and for example coupled to a ground terminal common to all of the pixels, with which is associated a hole transfer layer HTL located between the electrode E2 and the colloidal quantum dot CQD thin film (p-CQD).

Dielectric regions DL1 (for example silicon nitride or oxide, or resin, or other) summarily make it possible to laterally delimit the collection electrodes E1 as well as the respective electron transfer layers ETL. Dielectric regions DL2 may optionally be provided to laterally delimit reference electrodes E2 and/or respective hole transfer layers HTL.

This electron collection configuration is conventionally used because the read circuits usually operate with electrons.

However, this configuration has a problem of leakage between neighboring collection electrodes E1 when one is polarized to control an on state and the other an off state.

FIG. 1B illustrates in this respect the electrostatic potential in the CQD thin film subjected to such a polarization on a central electrode E1c at the potential of the on state and two lateral electrodes E1g, Eld at the potential of the off state on either side of the central electrode E1c.

FIG. 1C illustrates the level of the energy bands in eV (electronvolt) of the electrons and of the holes in the CQD thin film of FIG. 1B along the path VCUT between the reference electrode E2 and the central electrode E1c, and along the path HCUT between a lateral electrode E1d (or E1g by symmetry) and the central electrode E1c.

On the one hand, it can be seen on the path VCUT the “normal” migration in the presence of an electrical field of the electrons e− to the central electrode E1c and the migration of the holes h+ to the reference electrode E2.

On the other hand, it can be seen on the path HCUT the possibility of “leakage” of the electrons between the non-polarized lateral electrodes E1d (or E1g by symmetry) and the polarized central electrode E1c by crossing a very narrow potential barrier, according to the phenomenon usually referred to in the art as the “tunnel effect”.

FIG. 1D illustrates the total current density that results from the energy bands of the electrons e− on the path HCUT, between a lateral electrode E1g (or E1d by symmetry) and the central electrode E1c.

Thus, in particular, the stream FL of electrons e− from the non-polarized lateral electrode E1g (or E1d by symmetry) to the polarized central collection electrode E1c can be seen.

FIG. 1E illustrates the intensity of the currents I1g, I1d flowing on the lateral electrodes E1g and E1d and of the current I1c on the central collection electrode E1c, for example in the absence of incident light and of the photoelectric effect, depending on the polarization voltage of the central electrode of the photodiode. It can be seen that in these conditions the current I1c on the central electrode E1c equals the sum of the currents I1g, I1d flowing by leakage from the lateral electrodes E1g and E1d.

Thus, in the structure as described above, there is a problem of charges leaking from the non-polarized collection electrodes to the polarized collection electrode.

This problem generates difficulties particularly in applications selectively operating some of the pixels of which the photosensitive regions are located in the same common colloidal quantum dot CQD thin film, for example in two interlaced arrays of pixels, and alternatively collecting the photogenerated charges.

This is particularly the case of the following applications: a binning operating mode where a smaller number of pixels is selectively used, in order to benefit from a larger volume of photogenerated charges to increase the sensitivity; a plural operating mode (for example dual) where at least two arrays of pixels of different functions are interlaced and share the same colloidal quantum dot thin film.

Techniques for limiting the current leakage problems are typically based on the circuits for controlling and reading pixels, particularly using switching transistors to limit current leakage.

Such solutions consequently generate an additional size in the circuits for controlling each pixel, which may also be of significant complexity. This is in contrast with the reduction of the size of the pixels (and consequently limits the resolution of the sensor) and/or generates complex and costly designs, such as a stacking of a plurality of silicon wafers bonded with one another.

There is a need in the art to remedy the foregoing problems.

### SUMMARY

Embodiments herein address the problems by means of a configuration made on the energy bands of the photogenerated charges, based on the collection of holes instead of the collection of electrons, in such a way as to take advantage of a potential barrier preventing current leakage.

Apart from the absence of charge leakage, the architecture defined in the embodiments below eliminate the need for switching circuits for each collection electrode, which improves the integration.

Also, the embodiments defined below make a binning operation, and a plural operation possible, for example including an interlacing of various types of pixels, for example a static acquisition array of the global shutter type, an event-based acquisition array, and/or a time of flight measurement acquisition array.

According to one aspect, in this respect a photodetector device is proposed comprising at least one group of pixels including: a common reference electrode between the pixels; a continuous and common colloidal quantum dot thin film between the pixels including a photosensitive region capable of photogenerating electric charges; and an electrode for collecting the photogenerated charges respective to each pixel configured to collect positive electrically photogenerated charges.

The fact of configuring the collection electrodes, that is to say the means for reading the light signal detected by the device, to collect positive electrically photogenerated charges, referred to as “holes”, indeed makes it possible to benefit from a potential barrier effect preventing current leakage directly at the pixel architecture and therefore without requiring additional circuits in the control means.

According to one embodiment, the device includes a hole transfer layer between the colloidal quantum dot thin film and the respective collection electrodes. The hole transfer layer is configured to make it possible to transfer positive electric charges in an on state of the pixel, and to generate a sufficiently large electrostatic potential barrier to block the transfers of positive electric charges in an off state of the pixel.

According to one embodiment, the hole transfer layer may include in this respect a transparent metal oxide. The metal oxide is advantageously strongly doped so as to be used as hole extracting layers. For example, the hole transfer layer includes molybdenum oxide, nickel oxide, copper oxide, tungsten oxide, or vanadium oxide.

According to one embodiment, the colloidal quantum dot thin film may further include a P-type doped region at the interface with the hole transfer layer.

According to one embodiment, the device further includes a control circuit configured to selectively control the pixels in the on state or in the off state, by polarizing the common reference electrode at a reference voltage, and by respectively polarizing the collection electrodes.

According to one embodiment, the collection electrodes are configured to be polarized on polarization channels in direct contact on the respective collection electrodes in a manner devoid of switching means.

Indeed, the photosensitive region structure capable of photogenerating electric charges and the collection of positive charges photogenerated according to the aspect defined above, make an absence of current leakage possible with a control carried out by a polarization and consequently eliminate the need for palliative switching circuits for each collection electrode.

According to one embodiment, in a binning operating mode, the photodetector device is configured to collect the photogenerated charges in the colloidal quantum dot thin film, on the collection electrode of only one of the pixels of said at least one group of pixels.

In other words, in a “binning” application, a reduction of the resolution can be configured so as to increase the sensitivity. Conversely, as required, an increase of the resolution can be configured to the detriment of the sensitivity.

According to one embodiment, the pixels of said at least one group of pixels are of the same type dedicated to a photodetection of the same nature.

For example, the types of pixel dedicated to a photodetection of the same nature are dedicated to a photodetection of the same spectral component of light, such as a red, green, blue or infrared component.

According to one embodiment, said at least one group of pixels comprises a first type of pixel and a second type of pixel, the photodetector device being configured to collect the photogenerated charges in the colloidal quantum dot thin film, either on the collection electrodes of the pixels of the first type, or on the collection electrodes of the pixels of the second type.

According to one embodiment, the pixels of the first type and the pixels of the second type are each and distinctly configured for one of the following acquisitions: a static global shutter acquisition; a dynamic event-based detection acquisition; and a time of flight measurement.

### BRIEF DESCRIPTION OF THE DRAWINGS

Other advantages and features of the invention will become apparent upon examining the detailed description of non-limiting embodiments and implementations, and from the appended drawings, wherein:

FIG. 1A illustrates an example of photodetector pixels using a thin film of colloidal quantum dot CQD nanoparticles;

FIG. 1B illustrates in the electrostatic potential in the CQD thin film;

FIG. 1C illustrates the level of the energy bands of the electrons and of the holes in the CQD thin film of FIG. 1B;

FIG. 1D illustrates the total current density that results from the energy bands of the electrons;

FIG. 1E illustrates the intensity of the currents in the absence of incident light and of the photoelectric effect, depending on the polarization voltage of the central electrode of the photodiode;

FIG. 2 schematically illustrates the operating principle of a photodiode produced in a colloidal quantum dot CQD thin film;

FIG. 3 illustrates an example of embodiment of a pixel based on a photodiode in a colloidal quantum dot CQD thin film;

FIG. 4A illustrates an example of embodiment of a photodetector device;

FIG. 4B illustrates the electrostatic potential in the colloidal quantum dot CQD thin film;

FIG. 4C illustrates the level of the energy bands of the charge carriers in the colloidal quantum dot CQD thin film of FIG. 4B;

FIG. 4D illustrates the total current density that results from the configuration of the energy bands;

FIG. 4E illustrates the intensity of the currents flowing in the presence of incident light, depending on the polarization voltage of the photodiode;

FIG. 5 illustrates one example of binning operation of the photodetector device; and

FIG. 6 illustrates examples of plural operation including an interlacing of a plurality of types of pixels dedicated to various natures of photodetection.

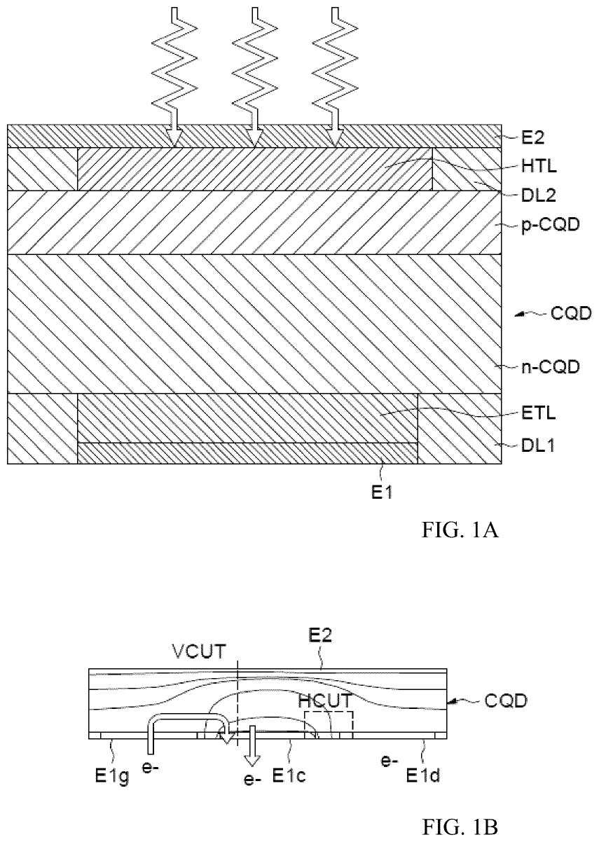

### DETAILED DESCRIPTION

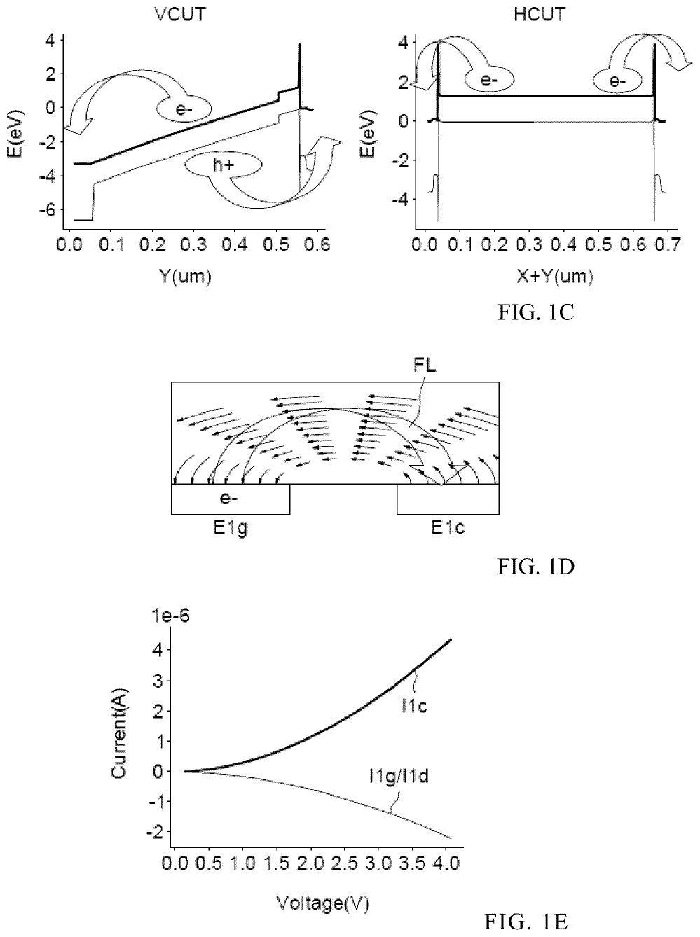

FIG. 2 schematically illustrates the operating principle of a photodiode produced in a colloidal quantum dot CQD thin film.

The photodiode is polarized between two electrodes with potentials V for modulating the external quantum effectiveness of the photoelectric generation, which is reflected in the intensity of the current I of the photodiode.

The photogenerated charges, that is to say the electric charges generated by the photoelectric effect, include electrons (represented by a single circle shape) and holes (represented by a double circle shape), and are respectively collected by an electron transfer layer ETL and by a hole transfer interface HTL, moreover connected to the electrodes controlling the photodiode.

The flow of the current I from the photogenerated charges depends on the modulation of the energy bands by the control potentials V.

Thus, the photodiode can be controlled in particular in a number of modes including: a blocked mode BLCK, that is to say an “OFF” state, wherein the charge carriers are in partial desertion and recombine in an electrically neutral area of the CQD thin film; a reverse mode RVRS, that is to say an “ON” state, wherein the charge carriers are in complete desertion in the CQD thin film, and benefiting from an absence of electrostatic barrier in the two charge transfer interfaces ETL, HTL (in the two electrodes); a reach through mode RCHT, at a threshold voltage Vrt between the blocked mode BLCK and the reverse mode RVRS, the charge carriers are completely deserted from the CQD thin film, and an electrostatic barrier is blocking at the electron transfer interface ETL; and a direct conduction mode DRCT, at positive control voltages, wherein a strong current is injected from the electrodes.

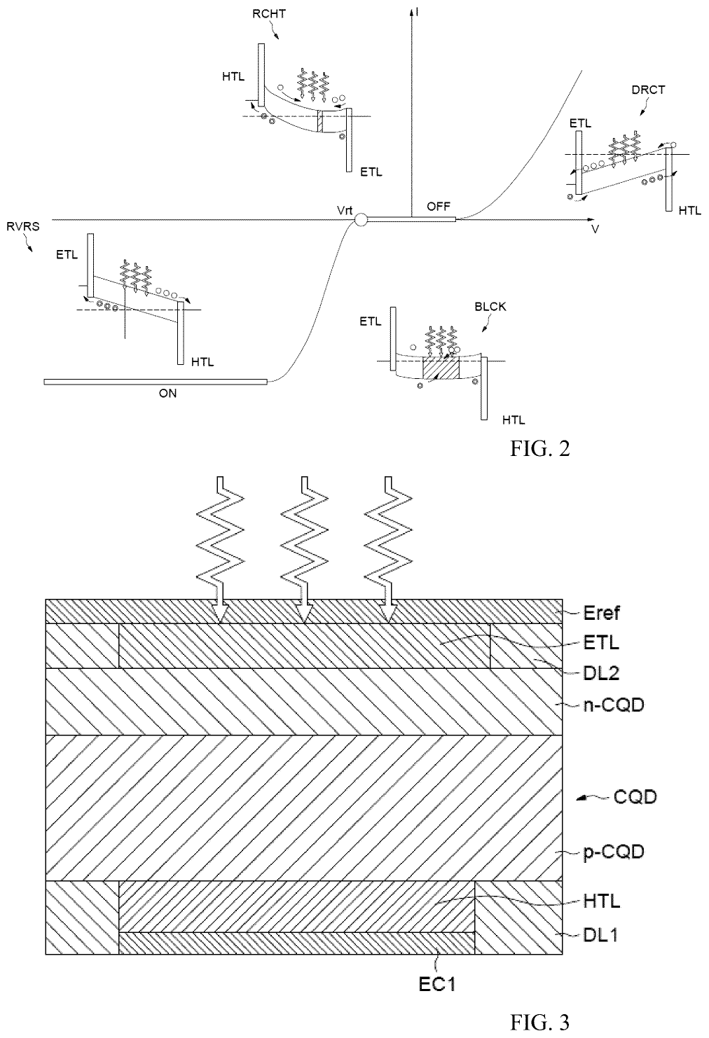

FIG. 3 illustrates an example of embodiment of a pixel based on a photodiode in a colloidal quantum dot CQD thin film. The pixel includes in particular: a reference electrode Eref; a colloidal quantum dot CQD thin film including a photosensitive region, called photodiode, capable of photogenerating electric charges, that is to say generating electric charges by photoelectric effect; and a collection electrode EC1.

Furthermore, the pixel includes: a hole transfer layer HTL located between the collection electrode EC1 and the colloidal quantum dot thin film p-CQD having a P-type doping, provided to transfer the photogenerated positive charges, called holes, so as to be collected on the collection electrode EC1; and an electron transfer layer ETL located between the reference electrode Eref and the colloidal quantum dot thin film n-CQD having a P-type doping, provided to transfer the photogenerated negative charges, called electrons, to a reference voltage node (the ground).

Dielectric regions DL1 (for example silicon nitride or oxide, or resin, or other) summarily make it possible to laterally delimit the collection electrode EC1 as well as the hole transfer layer HTL.

Dielectric regions DL2 may optionally be provided to laterally delimit the reference electrode Eref and/or the electron transfer layer ETL.

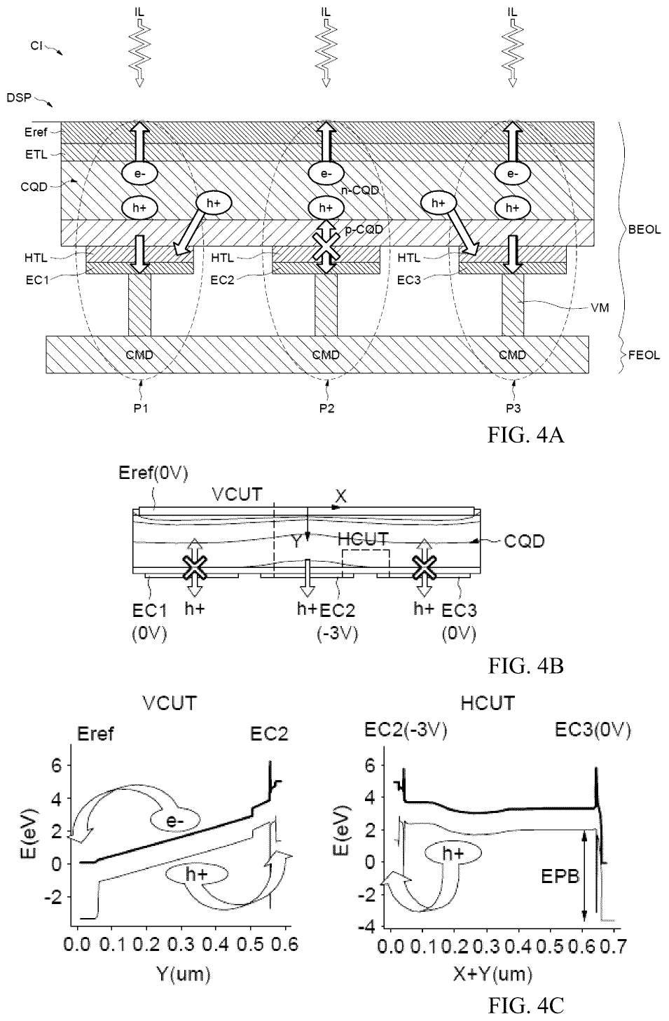

FIG. 4A illustrates an example of embodiment of a photodetector device DSP, typically belonging to an integrated circuit CI, comprising at least one group of pixels P1, P2, P3 using a colloidal quantum dot CQD thin film.

The device DSP particularly includes: a common reference electrode Eref between the pixels P1, P2, P3; a continuous and common colloidal quantum dot CQD thin film between the pixels P1, P2, P3 including a photosensitive region capable of photogenerating electric charges h+, e−; and an electrode EC1, EC2, EC3 for collecting the photogenerated charges respective to each pixel P1, P2, P3.

The electrodes EC1, EC2, EC3 for collecting the charges are configured to collect electrically positive photogenerated charges, called holes h+.

The reference electrode Eref, common to all of the pixels P1, P2, P3, is for its part configured to carry the negative electric photogenerated charges, called electrons e−, for example to a ground potential terminal.

The reference electrode Eref covers, for example, the external side of the colloidal quantum dot CQD thin film, that is to say the side that is exposed to the stream of incident light IL. Thus, the reference electrode Eref is manufactured from an electrically conductive material capable of being transparent for the incident light IL (depending for example on the material and/or the thickness thereof).

An electron transfer layer ETL, usually a metal oxide, capable of making it possible to transfer negative electric charges e− may advantageously be provided to create the interface between the colloidal film and the metal of the reference electrode Eref.

The collection electrodes EC1, EC2, EC3, for example made of copper, are located on the opposite side of the colloidal film CQD, and are connected to metal vias VM of an interconnection circuit BEOL (made in the context of the back end of line part of the manufacturing process) of the integrated circuit CI.

The metal vias VM electrically connect the collection electrodes EC1-EC3 to electronic circuits produced in a semiconducting part during front end of line (FEOL) manufacturing process steps. The electronic circuits are configured to implement the function of the device, particularly in terms of control and reading of the pixels (see below).

Advantageously, a hole transfer layer HTL is located between the colloidal quantum dot CQD film and the respective collection electrodes EC1, EC2, EC3. The hole transfer layer HTL is configured to make it possible to transfer positive electric charges h+ in an on state of the pixel, and to generate an electrostatic potential barrier that is sufficiently large to block the transfers of positive electric charges h+ in an off state of the pixel.

For example, the hole transfer layer HTL may include in this respect a transparent metal oxide of which the work function and the forbidden band are selected in such a way as to form an electrostatic potential barrier blocking the photogenerated holes h+ when the collection electrode EC2 is not polarized and allow them to all pass through when a control voltage is applied (EC1, EC3), for example less than or equal to 5 V for the targeted applications.

The metal oxide of the layer HTL is advantageously strongly doped so as to modulate the work function and the forbidden band in order to be used as hole extracting layer. For example, the hole transfer layer HTL includes molybdenum oxide, nickel oxide, copper oxide, tungsten oxide, or vanadium oxide.

Optionally, the hole transfer layer HTL may include in this respect a pCQD region including passivated quantum dots by ligands behaving as a P-type doped semiconductor. This pCQD layer makes it possible to passivate the nCQD layer. “Passivate” in this context is understood to mean “generating passivation”.

Thus, the pixels P1, P2, P3 include on the one hand a photosensitive region (colloidal quantum dot CQD thin film) between two electrodes Eref, EC1-EC3, and on the other hand control and read circuits in the circuit produced in the semiconducting part FEOL.

Colloidal quantum dot CQD thin films are technologies adapted to photodetection that make it possible to develop image sensors at low cost, high resolution and according to very good performances in the Short Wave Infra Red (SWIR), particularly in terms of outer quantum efficiency, of diaphony and of obscurity current.

Summarily, “quantum dots” usually designate formations of nanometric dimensions (for example less than 100 nm), including a core made of a semiconducting material, covered by molecules called ligands that extend radially outwardly from the core.

These formations draw their names of “quantum dots” due to the fact that they form a confinement area by quantum effect in all directions in space. The dimensions of the quantum dots are, for example, less than 100 nm, preferably between 2 nm and 15 nm.

The materials forming the quantum dots and the dimensions of each quantum dot, in particular the dimensions of the core, determine the adsorption wavelengths of the quantum dots, that is to say the wavelengths generating the photoelectric effect in the CQD photosensitive region.

The adsorption wavelengths correspond, for example, in the short-wave infrared, that is to say wavelengths between 700 nm and 1.6 μm, and/or in the mid-wave infrared, that is to say wavelengths between 1.6 μm and 4 μm, and/or in the visible, that is to say wavelengths between 300 nm and 700 nm.

The semiconductor core is, for example, a compound of lead sulphide, indium arsenide, or mercury telluride. The ligands are preferably made of organic molecules or organometallic and inorganic molecules.

The doping and the Fermi level of the colloidal quantum dot CQD thin film n-CQD, p-CQD is linked to the stoichiometry of the quantum dots, the net charge and the dipole moment of the ligands.

Indeed, the ligands may be molecules acting as N-type dopants, for example organic molecules such as thiolates; or molecules acting as P-type dopants, for example organic molecules of the carbon chain types.

Finally, a polarization of the colloidal quantum dot CQD thin film makes it possible to modulate the outer quantum efficiency of the photoelectric generation and of the recombination of charges, particularly between an “on” state where the intensity of the current that flows on the collection electrodes is the representation of the amount of photogenerated charge, and an “off” state where no current circulates regardless of the amount of photogenerated charge, the latter being recombined within the thin film due to the low diffusivity and mobility of the photogenerated charges in the absence of electric field. Reference is made to FIG. 2 in this regard.

In this respect, the photodetector device DSP advantageously further comprises a control circuit CMD configured to selectively control the pixels P1, P2, P3 in the on state, capable of collecting electrically positive photogenerated charges h+, or in the off state respectively incapable of collecting electrically positive photogenerated charges h+, by polarizing the common reference electrode Eref at a reference voltage, 0 V, and by respectively polarizing collection electrodes EC1, EC2, EC3.

In particular, it will be noted that the collection electrodes EC1, EC2, EC3 are configured to be polarized in order to control the on and off states of the pixels P1, P2, P3, and may consequently be accessed by polarization paths in direct contact on the respective collection electrodes EC1, EC2, EC3 in a manner devoid of switching means in particular.

Indeed, given the configuration made for collecting holes h+, and in particular the electrostatic potential barrier blocking the holes h+ at the collection electrodes EC1, EC3 in the off state, the device DSP benefits from an absence of current leakage between electrodes in the on state and in the off state.

In other words, the design of the CQD photosensitive region blocking the collected charges h+ by the potential barrier of the pixels P1, P3 in the off state, intrinsically eliminates the need to block the leakage of charges collected with the switching circuits for all of the pixels in the off state, when neighboring collection electrodes EC1, EC2, EC3 are distinctly polarized to control an on state and an off state.

Reference is made, in this respect, to FIGS. 4B, 4C, 4D and 4E.

FIG. 4B illustrates the electrostatic potential in the colloidal quantum dot CQD thin film subjected to a polarization wherein a collection electrode in central position EC2 is brought to the potential of the on state, for example −3 V, and two neighboring collection electrodes in lateral positions EC1, EC3, are brought to the potential of the off state, for example 0 V.

The collection electrode in central position EC2 will be designated “central electrode EC2” hereinafter, whereas the two collection electrodes in lateral positions EC1, EC3, located on either side of the central electrode EC2, will be designated “lateral electrodes EC1, EC3” hereinafter.

FIG. 4C illustrates the level of the energy bands in eV (electronvolt) of the charge carriers e−, h+ in the colloidal quantum dot CQD thin film of FIG. 4B along the vertical path VCUT between the reference electrode Eref and the central electrode EC2, and along the “lateral” path HCUT between a lateral electrode EC3 (or EC1 by symmetry) and the central electrode EC2.

On the one hand, it can be seen on the vertical path VCUT the “normal” migration of the holes h+ collected by the central electrode EC2 and the migration of the electrons e− to the ground supported by the reference electrode Eref.

On the other hand, it can be seen on the path HCUT the electrostatic potential barrier EPB preventing the migration of the holes h+ between the central electrode EC2 and the lateral electrodes EC3 (or EC1 by symmetry) by crossing a very narrow potential barrier, according to the phenomenon usually referred to as the “tunnel effect”.

The electrostatic potential barrier EPB thus prevents the migration of the holes h+, that is to say the positive photogenerated electric charges in the CQD photosensitive region, between two neighboring collection electrodes EC2, EC3 and supporting distinct potentials (i.e., potentials controlling an on state for example −3 V, and an off state for example 0 V).

FIG. 4D illustrates the total current density that results from the configuration of the energy bands of the holes h+ on the path HCUT, between a lateral electrode EC1 (or EC3 by symmetry) and the central electrode EC2.

Thus, it can be seen that there is no stream of positive charges h+ from the lateral electrode EC1 (or EC3 by symmetry) to the central collection electrode EC2, and that there are streams FL1, FL2 globally directing the positive charges h+ of the volume from the CQD photosensitive region to the central electrode EC2.

FIG. 4E illustrates the intensity of the currents I1, I3 flowing on the lateral electrodes EC1 and EC3 and of the current I2 on the central EC2, for example in the presence of incident light, depending on the polarization voltage of the photodiode.

It can be seen in these conditions that the currents I1, I3 are strictly zero on the lateral electrodes EC1 and EC3, whereas the current I2 on the central electrode EC2 flows from control voltages of the on state less than −2.5 V, for example −3 V.

Thus, in the device DSP described above in relation to FIGS. 4A to 4E, there is no problem of charges leaking between the neighboring collection electrodes at various potentials.

Consequently, the device DSP makes advantageous and efficient applications possible, particularly for a binning operation and/or a plural operation.

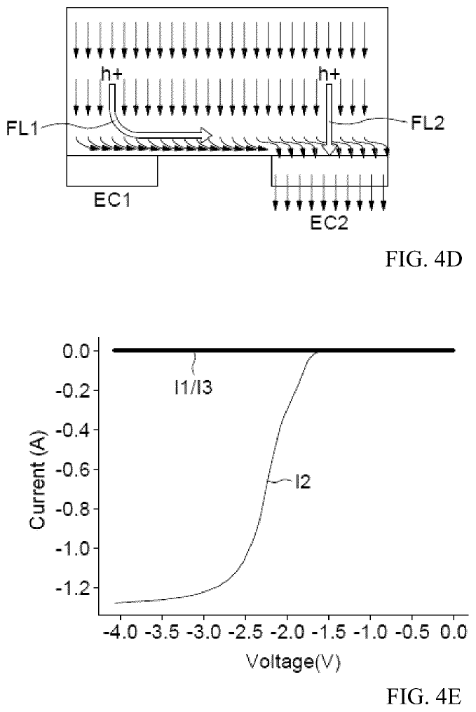

FIG. 5 illustrates one example of binning operation of the photodetector device DSP.

In the binning operating mode, a smaller number of pixels is selectively used to collect charges in a given volume of the photosensitive region. This makes it possible to increase the sensitivity of the detection in order to increase the operating speed, as well as the capacity to detect events, while reducing the associated noise.

Indeed, the photodetector device DSP is, for example, configured to collect the photogenerated charges in the photosensitive region (colloidal quantum dot CQD thin film), on the collection electrode of only one of the pixels PXon of a group of pixels GRP.

The pixel PXon collecting the charges of the group is controlled in the on state, and is thus designated “on pixel” of the group, whereas all of the other pixels PXoff of the group GRP are controlled in the off state, and are thus designated “off pixels” of the group.

It is reminded that the off pixels PXoff make it possible to photogenerate the charges h+ in the associated photosensitive region, but prevent the flow of the current from holes h+ on their collection electrode.

Thus, the charges h+ generated in the photosensitive region of all of the pixels of the group GRP are collected by the single on pixel PXon of the group GRP.

In this respect, the on pixel PXon is selected at a position in the group GRP making it possible to be as close as possible to the location for generating the charges. For example, the on pixel PXon of the group is selected at a central position, for example in the middle of a group of 9 pixels in a square of 3×3 pixels. Other arrangements of pixels may be provided to form groups GRP adapted to the billing.

In this example the pixels of the groups of pixels GRP are dedicated to the same nature of photodetection, that is to say, for example, that all of the pixels of the group GRP are dedicated to a static global shutter detection of the components of the visible, red R, green G and blue B, respectively in each group GRPG, GRPR, GRPB.

Conversely, as required, each pixel of the group GRP can be controlled individually, for example in order to increase the resolution to the detriment of the sensitivity, possibly by means of a remosaicing technique, that is to say rearranging by extrapolation into a basic pattern (or mosaic), for example of the Bayer type.

Alternatively, the pixels of the groups of pixels GRP are dedicated to various natures of photodetection.

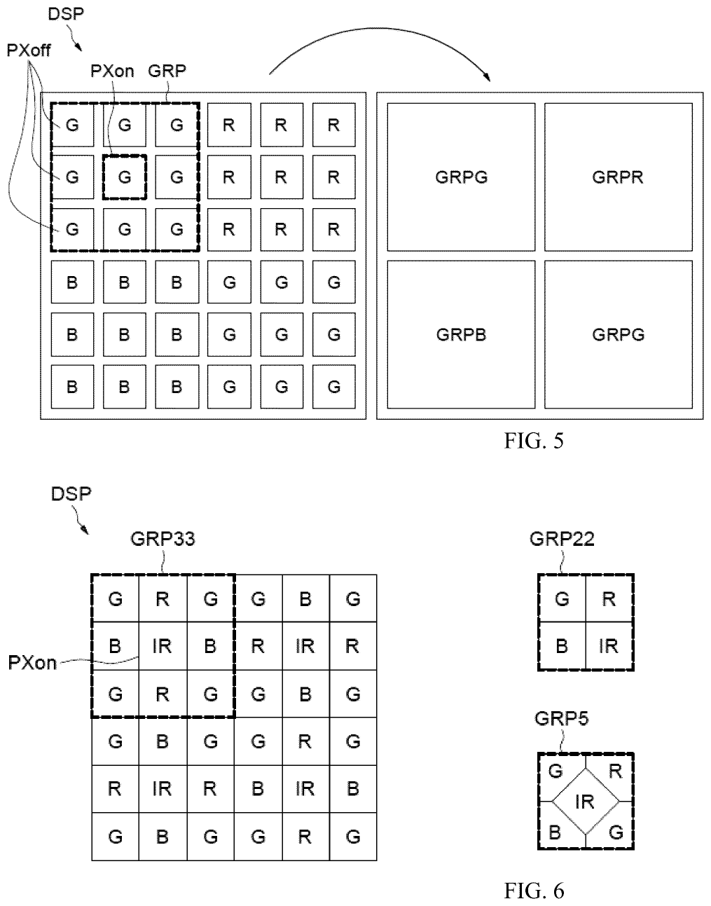

In this respect, reference is made to FIG. 6. FIG. 6 illustrates examples of plural operation, for example including an interlacing of a plurality of types of pixels dedicated to various natures of photodetection, for example: a static acquisition array with global shutter or rolling shutter, an event-based acquisition array (IR), and/or a time of flight measurement acquisition array (IR).

Thus, the device DSP includes at least two arrays of pixels of different functions, are interlaced and share the same colloidal quantum dot CQD thin film.

In practice, to avoid too much complexity, it is advantageous to implement a dual operation, including an interlacing of two types of pixels dedicated to various natures of photodetection.

Thus, in a first example, some of the pixels of the groups of pixels GRP33, GRP22, GRP5, are dedicated to a static global shutter acquisition of the components of the visible R, G, B, and others to a dynamic event-based detection acquisition of an infrared component IR.

In a second example, some of the pixels R, G, B of the groups of pixels GRP33, GRP22, GRP5, are dedicated to a static global shutter acquisition of the components of the visible RGB, and others to an avalanche effect for a time of flight measurement of an infrared IR component.

In these two examples, each group GRP33 includes pixels R, G, B, dedicated to acquisitions made in the visible, red, green and blue, and at least one pixel IR dedicated to the acquisitions made in the infrared.

For example, the group GRP33 includes nine pixels in a square of 3×3 pixels, comprising two red pixels R, four green pixels G, two blue pixels B, and an infrared pixel IR at the position in the middle of the square.

For example, the group GRP22 includes four pixels in a square of 2×2 pixels, comprising a red pixel R, a green pixel, a blue pixel and an infrared pixel IR.

For example, the group GRP5 includes five pixels in a square of 2×2 pixels, comprising a red pixel R, two green pixels, and a blue pixel, with an infrared pixel IR additionally positioned in the middle of the square.

By providing red, green and blue filters transparent to the infrared component, then the binning technique can be applied by controlling the infrared pixel IR as on pixel PXon of the group GRP, in order to benefit from the increase of the sensitivity and of the speed, while reducing the associated noise.

For example, within this scope of plural detections, it will be possible to implement said global shutter, event-based, or time of flight measurement acquisitions during acquisition phases distinct from one another.

During distinct acquisition phases, this will thus give either the first type of pixel controlled in the on state and the second type of pixel controlled in the off state, or the first type of pixel controlled in the off state and the second type of pixel controlled in the on state.

In this case, the photodetector device is configured to collect the photogenerated charges in the photosensitive regions common to the group GRP33, GRP22, GRP5, either with the first type of pixel (for example the pixels of the visible R, G, B), or with the second type of pixel (for example the infrared IR pixel).

In both cases, the collected currents will not be marred with leakage between neighboring collection electrodes respectively controlling the on and off states.

1. A photodetector device, comprising at least one group of pixels, including:
a common reference electrode between pixels of the at least one group of pixels;
a continuous and common colloidal quantum dot thin film shared between the pixels of the at least one group of pixels including a photosensitive region capable of photogenerating electric charges; and
an electrode for collecting photogenerated electric charges respective to each pixel, wherein the electrodes for collecting the photogenerated electric charges are configured to collect electrically positive photogenerated electric charges.

2. The photodetector device according to claim 1, including a hole transfer layer between the colloidal quantum dot thin film and the respective electrodes for collecting photogenerated electric charges, wherein the hole transfer layer is configured to transfer positive electric charges when the pixel is in a pixel on state, and to generate an electrostatic potential barrier that is sufficiently large to block the transfers of positive electric charges when the pixel is in a pixel off state.

3. The photodetector device according to claim 2, wherein the hole transfer layer includes a transparent metal oxide.

4. The photodetector device according to claim 2, wherein the colloidal quantum dot thin film includes a P-type doped region at the interface with the hole transfer layer.

5. The photodetector device according to claim 2, further including a control circuit configured to selectively control the pixels, in the pixel on state or in the pixel off state, by polarizing the common reference electrode at a reference voltage, and by respectively polarizing the electrodes for collecting photogenerated charges.

6. The photodetector device according to claim 5, wherein the pixels of said at least one group of pixels are dedicated to a same nature of photodetection.

7. The photodetector device according to claim 2, wherein the electrodes for collecting photogenerated charges are configured to be polarized on polarization paths in direct contact on the respective electrodes for collecting photogenerated charges in a manner devoid of a switching circuit.

8. The photodetector device according to claim 1, wherein, in a binning operating mode, the photodetector device is configured to collect the photogenerated charges in the colloidal quantum dot thin film on the electrode for collecting photogenerated charges of only one of the pixels of said at least one group of pixels.

9. The photodetector device according to claim 1, wherein said at least one group of pixels comprises a first type of pixel and a second type of pixel, and the device is configured to collect the photogenerated charges in the colloidal quantum dot thin film, either on the electrodes for collecting photogenerated charges of the pixels of the first type, or one of the electrodes for collecting photogenerated charges of the pixels of the second type.

10. The photodetector device according to claim 9, wherein the pixels of the first type and the pixels of the second type are each and distinctly configured for one of the following acquisitions:
a static global shutter acquisition;
a dynamic event-based detection acquisition; or
a time of flight measurement.

11. A photodetector device, comprising at least one group of pixels, including:
a common reference electrode between pixels of the at least one group of pixels;
a continuous and common colloidal quantum dot thin film shared between the pixels of the at least one group of pixels including a photosensitive region configured to photogenerate electric charges;
an electrode for collecting photogenerated electric charges respective to each pixel; and
a transfer layer between the colloidal quantum dot thin film and the respective electrodes for collecting photogenerated electric charges, wherein the transfer layer is configured to transfer electric charges when the pixel is in a pixel on state, and to generate an electrostatic potential barrier that is sufficiently large to block the transfers of electric charges when the pixel is in a pixel off state.

12. The photodetector device according to claim 11, wherein the transfer layer includes a transparent metal oxide.

13. The photodetector device according to claim 11, further including a control circuit configured to selectively control the pixels in the pixel on state by polarizing the common reference electrode at a reference voltage and in the pixel off state by polarizing the electrodes for collecting photogenerated charges.

14. The photodetector device according to claim 11, wherein the photodetector device is configured to collect the photogenerated charges when operating in a binning mode in the colloidal quantum dot thin film on the electrode for collecting photogenerated charges of only one of the pixels of said at least one group of pixels.

15. The photodetector device according to claim 11, wherein the pixels of the at least one group of pixels are configured for acquisition in a static global shutter acquisition mode.

16. The photodetector device according to claim 11, wherein the pixels of the at least one group of pixels are configured for acquisition in a dynamic event-based detection acquisition mode.

17. The photodetector device according to claim 11, wherein the pixels of the at least one group of pixels are configured for acquisition in a time of flight measurement mode.
